(19) United States
(12) Patent Application Publication
(10) Pub. No.: US 2026/0040764 A1
(43) Pub. Date: Feb. 5, 2026

(54) DEVICE PROTECTED LAYER FOR OLED ADVANCED PATTERNING

(71) Applicant: Applied Materials, Inc., Santa Clara, CA (US)

(72) Inventors: Sheng-Wen WANG, Tainan City (TW); Chung-chia CHEN, Hsinchu City (TW); Ji Young CHOUNG, Hwaseong-si (KR); Yu-Hsin LIN, Zhubei City (TW)

(21) Appl. No.: 19/098,719

(22) Filed: Apr. 2, 2025

Related U.S. Application Data
(60) Provisional application No. 63/677,122, filed on Jul. 30, 2024.

(51) Int. Cl. H10K 59/122; H10K 59/12; H10K 59/80

(52) U.S. Cl. CPC H10K 59/122; H10K 59/1201; H10K 59/873

(57) ABSTRACT

Embodiments described herein generally relate to a display. More specifically, embodiments described herein relate to sub-pixel circuits and methods of forming sub-pixel circuits that may be utilized in a display such as an organic light-emitting diode (OLED) display. In one example, a first sub-pixel includes a first anode, a first organic light-emitting (OLE) material, a first cathode disposed over the first OLE material, a first encapsulation layer, and a first protection layer disposed on the first encapsulation layer extending under at least a portion of the overhang structures and along a sidewall of the first structure. The second sub-pixel includes a second anode, a second OLE material, a second cathode disposed over the second OLE material, a second encapsulation layer, and a second protection layer disposed on the second encapsulation layer extending under at least the portion of the overhang structures and along the sidewall of the first structure.

### CROSS-REFERENCE TO RELATED APPLICATIONS

This application claims priority to U.S. Provisional Patent Application Ser. No. 63/677,122, filed on Jul. 30, 2024, which is herein incorporated by reference in its entirety.

### BACKGROUND

### Field

Embodiments of the present disclosure generally relate to a display. More specifically, embodiments described herein relate to pixels and methods of forming pixels that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance.

Accordingly, what is needed in the art are OLED pixels and method of forming OLED pixels to increase pixel-per-inch and provide improved OLED performance.

### SUMMARY

In one embodiment, a device is provided. The device includes a substrate, a plurality of overhang structures, each overhang structure defined a second structure disposed over a first structure, the second structure extending laterally past the first structure, adjacent overhang structures of the plurality overhang structures define a plurality of sub-pixels including a first sub-pixel and a second sub-pixel. The first sub-pixel includes a first anode, a first organic light-emitting (OLE) material, a first cathode disposed over the first OLE material, a first encapsulation layer, and a first protection layer disposed on the first encapsulation layer extending under at least a portion of the overhang structures and along a sidewall of the first structure. The second sub-pixel includes a second anode, a second OLE material, a second cathode disposed over the second OLE material, a second encapsulation layer, and a second protection layer disposed on the second encapsulation layer extending under at least the portion of the overhang structures and along the sidewall of the first structure.

In another embodiment, a device is provided. The device includes a substrate, a plurality of overhang structures, each overhang structure defined a second structure disposed over a first structure, the second structure extending laterally past the first structure, adjacent overhang structures of the plurality overhang structures define a plurality of sub-pixels including a first sub-pixel and a second sub-pixel. The first sub-pixel includes a first anode, a first organic light-emitting (OLE) material, a first cathode disposed over the first OLED, a first encapsulation layer, a first protection layer disposed on the first encapsulation layer extending under at least a portion of the overhang structures and along a sidewall of the first structure, and a second protection layer disposed on the first protection layer. The second sub-pixel includes a second anode, a second OLE material, a second cathode disposed over the second OLE material, a second encapsulation layer, and the second protection layer disposed on the second encapsulation layer extending under at least the portion of the overhang structures and along the sidewall of the first structure.

In another embodiment, a method is provided. The method includes disposing a first organic light-emitting (OLE) material, a first cathode, a first encapsulation layer, and a first protection layer over a substrate, the substrate having a plurality of overhang structures, each overhang structure is defined by a second structure disposed over a first structure, the second structure extending laterally past the first structure, adjacent overhang structures of the plurality overhang structures define a plurality of sub-pixels including at least a first sub-pixel and a second sub-pixel. A resist is formed in a well of the first sub-pixel and the method further includes removing the first protection layer, the first cathode, the first OLE material, and the first encapsulation layer exposed by the resist, removing the resist in the well of the first sub-pixel, disposing a second OLE material, a second cathode, a second encapsulation layer, and a second protection layer over the substrate, forming a resist in the well of the second sub-pixel, and removing the second protection layer, the second cathode, and the second OLE material, and the second encapsulation layer exposed by the resist.

In yet another embodiment, a method is provided. The method includes providing a substrate having a first well of a first sub-pixel defined by adjacent overhang structures disposed over the substrate, disposing a first organic light-emitting (OLE) material, a first cathode, and a first encapsulation layer, forming a first resist in a well of the first sub-pixel, removing the first OLE material, the first cathode, and the first encapsulation layer exposed by the first resist, removing the first resist, disposing a first protection layer over the substrate, forming a second resist over the first sub-pixel to expose an area of a second sub-pixel, etching a second layer and a first layer to form a well of a second sub-pixel, disposing a second OLE material, a second cathode, and a second encapsulation layer over the substrate, forming a third resist in the well of the second sub-pixel, removing the second OLE material, the second cathode, and the second encapsulation layer exposed by the third resist, and depositing a second protection layer over the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit having a first protection configuration according embodiments described herein.

FIG. 1B is a schematic, cross-sectional view of a sub-pixel circuit having a second protection configuration according embodiments described herein.

FIG. 1C is a schematic, cross-sectional view of a sub-pixel circuit having a third protection configuration according embodiments described herein.

FIG. 1D is a schematic, cross-sectional view of a sub-pixel circuit having a fourth protection configuration according embodiments described herein.

FIG. 2 is a flow diagram of a method for forming a sub-pixel circuit according embodiments described herein.

FIGS. 3A-3D are schematic, cross-sectional views of a substrate during a method for forming a sub-pixel circuit according embodiments described herein.

FIG. 4 is a flow diagram of a method for forming a sub-pixel circuit according embodiments described herein.

FIGS. 5A-5H are schematic, cross-sectional views of a substrate during a method for forming a sub-pixel circuit according embodiments described herein.

FIG. 6 is a flow diagram of a method for forming a sub-pixel circuit according embodiments described herein.

FIGS. 7A-7F are schematic, cross-sectional views of a substrate during a method for forming a sub-pixel circuit according embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In one embodiment, which can be combined with other embodiments described herein, the display is a bottom emission (BE) or a top emission (TE) OLED display. In another embodiment, which can be combined with other embodiments described herein, the display is a passive-matrix (PM) or an active matrix (AM) OLED display.

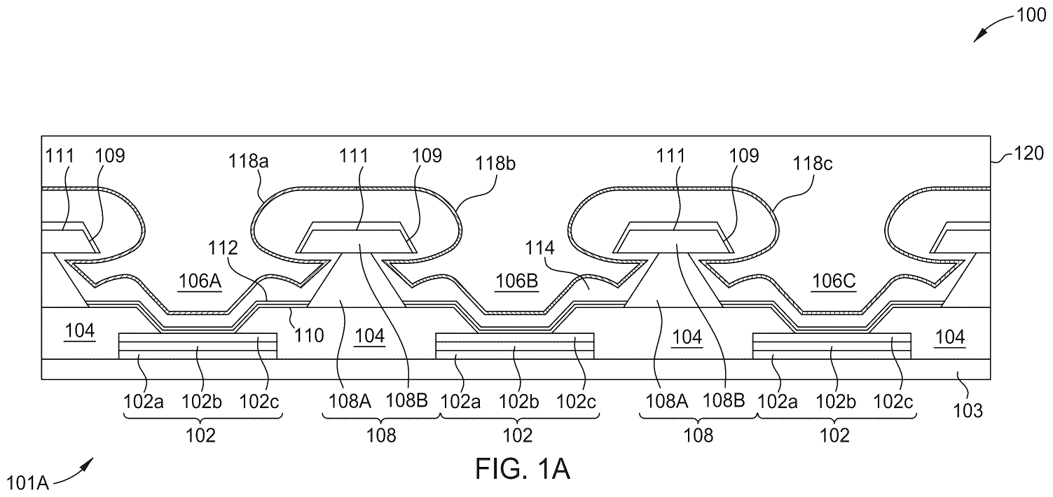

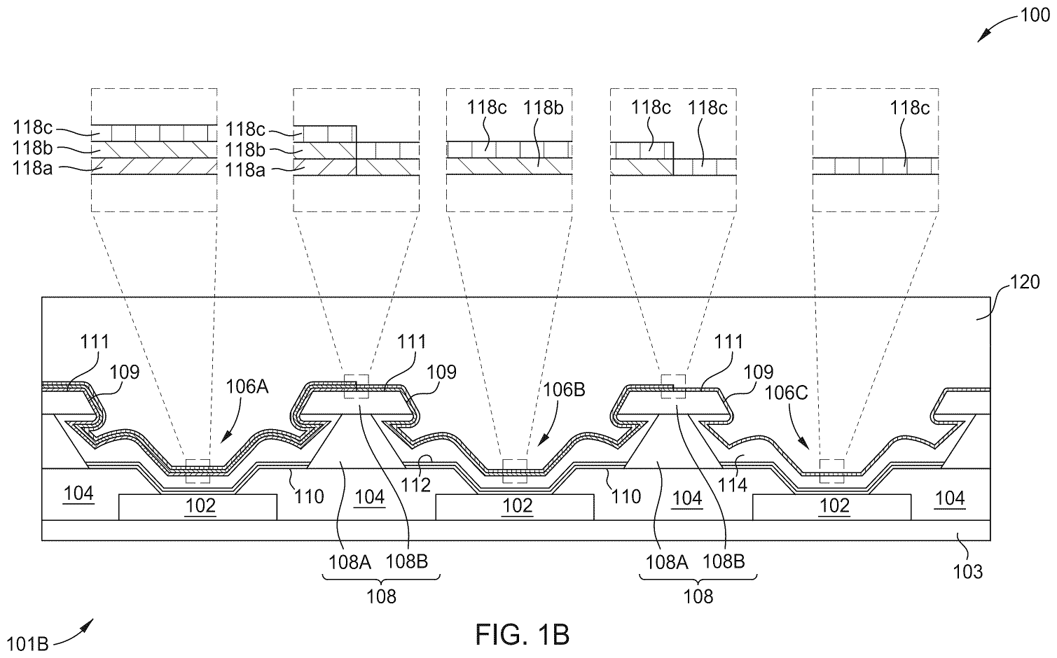

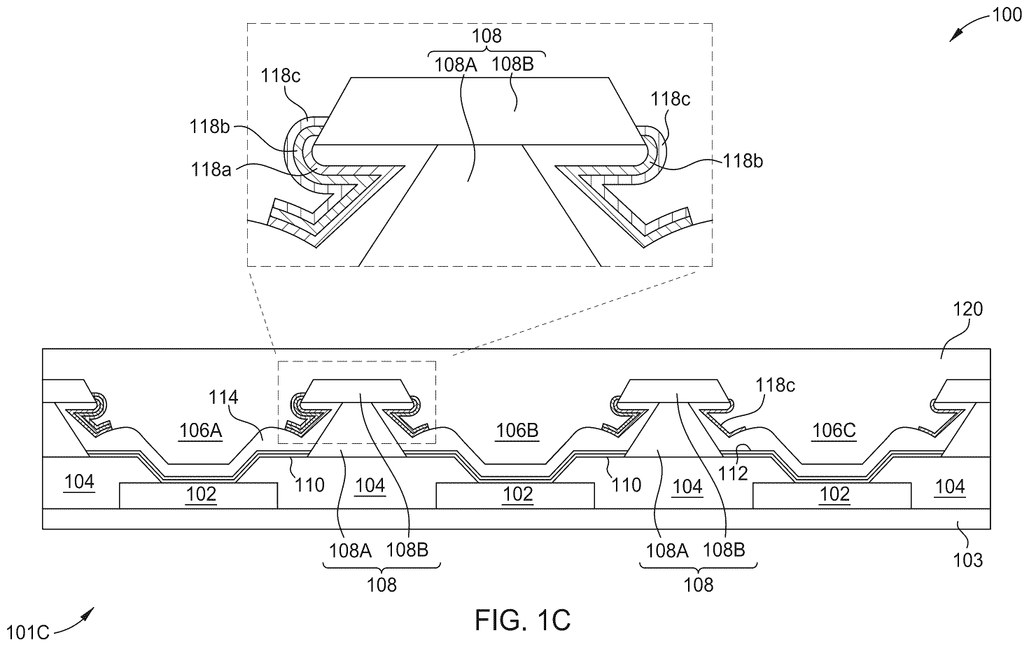

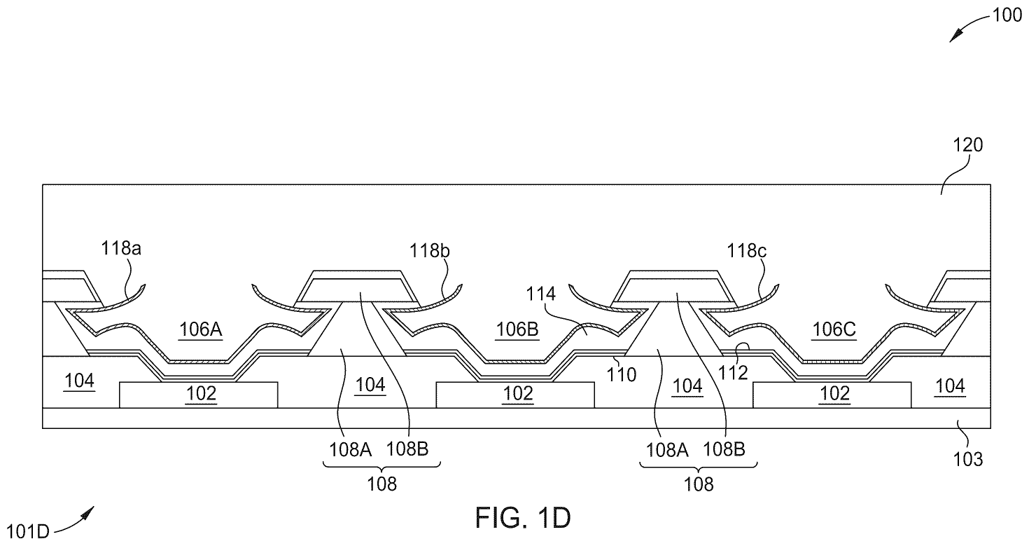

FIG. 1A is a schematic, cross-sectional view of a sub-pixel circuit 100 having a first protection configuration 101A. FIG. 1B is a schematic, cross-sectional view of a sub-pixel circuit 100 having a second protection configuration 101B. FIG. 1C is a schematic, cross-sectional view of a sub-pixel circuit 100 having a third protection configuration 101C. FIG. 1D is a schematic, cross-sectional view of a sub-pixel circuit 100 having a fourth protection configuration 101D.

The sub-pixel circuit 100 includes a plurality of anodes 102 disposed over a substrate 103. The substrate 103 is a backplane. The backplane includes, but is not limited to, a complementary metal-oxide-semiconductor (CMOS) array or a thin-film transistor (TFT) array. Each anode 102 includes at least one metal-containing layer. Each anode 102 may include a first metal-containing layer 102a, a second metal-containing layer 102b disposed over the first metal-containing layer 102a, and a third metal-containing layer 102c disposed over the second metal-containing layer 102b. While the first metal-containing layer 102a, the second metal-containing layer 102b, and the third metal-containing layer 102c are shown for an anode of the first sub-pixel 106A, each sub-pixel may include an anode with the first metal-containing layer 102a, the second metal-containing layer 102b, and third metal-containing layer 102c. The metal-containing layers include, but are not limited to, chromium, titanium, gold, silver, copper, aluminum, ITO, or combinations thereof. In one or more embodiments, the first metal-containing layer 102a is a first transparent conductive oxide (TCO) layer, the second metal-containing layer 102b is disposed on the first TCO layer, and the third metal-containing layer 102c is a third TCO layer disposed on the second metal-containing layer. The TCO material includes, but is not limited to, indium zinc oxide (IZO), indium tin oxide (ITO), indium gallium zinc oxide (IGZO), or combinations thereof. The first metal-containing layer 102a, a second metal-containing layer 102b disposed over the first metal-containing layer 102a, and a third metal-containing layer 102c.

Isolation structures 104 are disposed on or over the substrate 103. The Isolation structures 104 include one of an organic material, an organic material with an inorganic coating disposed thereover, or an inorganic material. The organic material of the Isolation structures 104 includes, but is not limited to, polyimides. The inorganic material of the Isolation structures 104 includes, but is not limited to, silicon oxide (SiO₂), silicon nitride (Si₃N₄), silicon oxynitride (Si₂N₂O), magnesium fluoride (MgF₂), or combinations thereof. Adjacent Isolation structures 104 expose an upper surface of the plurality of anodes 102.

The sub-pixel circuit 100 has a plurality of sub-pixels including at least a first sub-pixel 106A, a second sub-pixel 106B, and a third sub-pixel 106C. While the Figures depict the first sub-pixel 106A, the second sub-pixel 106B, and the third sub-pixel 106C. The sub-pixel circuit 100 of the embodiments described herein may include two or more sub-pixels, such as a fourth sub-pixel. Each sub-pixel has organic light-emitting (OLE) material 110 configured to emit a white, red, green, blue or other color light when energized. E.g., the OLE material 110 of the first sub-pixel 106A emits a red light when energized, the OLE material of the second sub-pixel 106B emits a blue light when energized, the OLE material of a third sub-pixel emits a green light when energized, and the OLE material of a fourth sub-pixel emits another color light, blue, green, or red light, or white when energized

Overhang structures 108 are disposed on or over an upper surface of each of the isolation structures 104. The overhang structures 108 are inorganic. The overhang structures 108 are permanent to the sub-pixel circuit. The overhang structures 108 define each sub-pixel of the sub-pixel circuit 100. The overhang structures 108 include at least a second structure 108B disposed on or over a first structure 108A. A first configuration of the overhang structures 108 includes the second structure 108B of a non-conductive inorganic material and the first structure 108A of a conductive inorganic material. A second configuration of the overhang structures 108 includes the second structure 108B of a conductive inorganic material and the first structure 108A of a conductive inorganic material. Thus, organic material from lifted off overhang structures that disrupt OLED performance would not be left behind. Eliminating the need for a lift-off procedure also increases throughput.

The non-conductive inorganic material includes, but it not limited to, an inorganic silicon-containing material. E.g., the silicon-containing material includes oxides or nitrides of silicon, or combinations thereof. The conductive inorganic material includes, but it not limited to, a metal-containing material. E.g., the metal-containing material includes copper, titanium, aluminum, molybdenum, silver, indium tin oxide, indium zinc oxide, chromium or combinations thereof.

At least a bottom surface of the second structure 108B is wider than a top surface of the first structure 108A to form an overhang. The bottom surface larger than the top surface forming the overhang allows for the second structure 108B to shadow the first structure 108A. The shadowing of the overhang provides for evaporation deposition each of the OLE material 110 and a cathode 112.

The OLE material 110 may include one or more of a HIL, a HTL, an EML, and an ETL. The OLE material 110 is disposed over the anodes 102. In some embodiments, which can be combined with other embodiments described herein, the OLE material 110 is disposed on the anodes 102 and over a portion of the Isolation structures 104. The cathode 112 is disposed on or over the OLE material 110 of the Isolation structures 104 in each sub-pixel. The cathode 112 includes a conductive material, such as a metal. E.g., the cathode 112 includes but is not limited to, silver, chromium, titanium, aluminum, ITO, magnesium, or a combination thereof. The assistant cathode includes, but it not limited to, a metal-containing material. For example, the metal-containing material includes copper, titanium, aluminum, molybdenum, silver, indium tin oxide, indium zinc oxide, chromium or combinations thereof. In some embodiments, the material of the cathode 112 and the second structure 108B are different from each other.

Each sub-pixel includes a respective encapsulation layer 114. As shown in FIGS. 1A-1D, the sub-pixel circuit 100 include three encapsulation layers 114, each encapsulation layer respective to each sub-pixel. Each encapsulation layer 114 may be or may correspond to a local passivation layer. The encapsulation layer 114 of a respective sub-pixel is disposed over the cathode 112 (and OLE material 110). The encapsulation layer of at least one sub-pixel is disposed over the cathode 112 and past an endpoint of the cathode 112. The encapsulation layer 114 extends under at least a portion of the overhang structures 108 along a sidewall of the first structure 108A and contacts the bottom surface of the second structure 108B of the overhang structures 108. As shown in FIG. 1A, the encapsulation layer 114 is disposed over the upper sidewall 109 of the second structure 108B. As shown in FIG. 1A, the encapsulation layer 114 is disposed over an upper surface 111 of the second structure 108B. The encapsulation layer 114 includes a non-conductive inorganic material. The non-conductive inorganic material, includes but is not limited to, a silicon-containing material. An example of the silicon-containing material is silicon nitride. In other embodiments, the encapsulation layer 114 includes a silicon nitride material, silicon oxynitride material, silicon oxide material, or a combination thereof. A global passivation layer 120 is disposed over the encapsulation layers 114 and the overhang structures 108.

The first protection configuration 101A, as shown in FIG. 1A, includes at least a first protection layer 118a disposed in the well of the first sub-pixel 106A and a second protection layer 118b disposed in the well of the second sub-pixel 106B. The first protection configuration 101A may further include a third protection layer 118c disposed in the well of the third sub-pixel 106C. The first protection layer 118a is disposed over the encapsulation layer 114 of the first sub-pixel 106A that extends under at least a portion of the overhang structures 108 along a sidewall of the first structure 108A, contacts the bottom surface of the second structure 108B, and is disposed over the second structure 108B. The second protection layer 118b is disposed over the encapsulation layer 114 of the second sub-pixel 106B that extends under at least a portion of the overhang structures 108 along a sidewall of the first structure 108A, contacts the bottom surface of the second structure 108B, and is disposed over the second structure 108B.

As shown in FIG. 1B of the second protection configuration 101B, the first protection layer 118a is disposed over the encapsulation layer 114 of the first sub-pixel 106A that extends under at least a portion of the overhang structures 108 along a sidewall of the first structure 108A, and contacts the bottom surface of the second structure 108B. The first protection layer 118a is disposed over the upper sidewall 109 and the upper surface 111 of the second structure 108B. The first sub-pixel 106A includes the second protection layer 118b disposed over the first protection layer 118a. In some embodiments, the first sub-pixel 106A includes the third protection layer 118c disposed over the second protection layer 118b. The second protection layer 118b is disposed over the encapsulation layer 114 of the second sub-pixel 106B that extends under at least a portion of the overhang structures 108 along a sidewall of the first structure 108A, and contacts the bottom surface of the second structure 108B. The second protection layer 118b is disposed over the upper sidewall 109 and the upper surface 111 of the second structure 108B. In some embodiments, the second sub-pixel 106B includes the third protection layer 118c disposed over the second protection layer 118b. In some embodiments, the third protection layer 118c is disposed over the encapsulation layer 114 of the third sub-pixel 106C that extends under at least a portion of the overhang structures 108 along a sidewall of the first structure 108A, and contacts the bottom surface of the second structure 108B. The third protection layer 118c, when included, is disposed over the upper sidewall 109 and the upper surface 111 of the second structure 108B.

As shown in FIG. 1C of the third protection configuration 101C, the first protection layer 118a contacts the bottom surface of the second structure 108B of the overhang structures 108 and extends under at least a portion of the overhang structures 108 along a sidewall of the first structure 108A. The first sub-pixel 106A includes the second protection layer 118b disposed over the first protection layer 118a. The second protection layer 118b is disposed adjacent to the upper sidewall 109 of the second structure 108B. The third protection layer 118c is disposed over the second protection layer 118b in the first sub-pixel 106A. The second protection layer contacts the bottom surface of the second structure 108B of the overhang structures 108 and extends under at least a portion of the overhang structures 108 along a sidewall of the first structure 108A. The second sub-pixel 106B includes the third protection layer 118c disposed over the second protection layer 118b. The third protection layer 118c is disposed adjacent to the upper sidewall 109 of the second structure 108B. The third protection layer 118c of the third sub-pixel 106C contacts the bottom surface of the second structure 108B of the overhang structures 108, and extends under at least a portion of the overhang structures 108 along a sidewall of the first structure 108A.

As shown in FIG. 1D of the fourth protection configuration 101D, the first protection layer 118a is disposed over the encapsulation layer 114 of the first sub-pixel 106A that extends under at least a portion of the overhang structures 108 along a sidewall of the first structure 108A, and contacts the bottom surface of the second structure. The second protection layer 118b is disposed over the encapsulation layer 114 of the second sub-pixel 106B that extends under at least a portion of the overhang structures 108 along a sidewall of the first structure 108A, and contacts the bottom surface of the second structure 108B. In some embodiments, the third protection layer 118c is disposed over the encapsulation layer 114 of the third sub-pixel 106C that extends under at least a portion of the overhang structures 108 along a sidewall of the first structure 108A and contacts the bottom surface of the second structure 108B. The third protection layer 118c, when included, is disposed over the upper sidewall 109 and the upper surface 111 of the second structure 108B. The first protection layer 118a and the encapsulation layer 114 of the first sub-pixel 106A have a gap therebetween. The second protection layer 118b and the encapsulation layer 114 of the second sub-pixel 106B have a gap therebetween. The third protection layer 118c and the encapsulation layer 114 of the third sub-pixel 106C have a gap therebetween. The global passivation layer 120 is disposed over the encapsulation layers 114 and the overhang structures 108, and is disposed in the gaps.

The material of the protection layers includes, but is not limited to, a metal-containing material, a transparent conductive oxide (TCO) containing material, or a dielectric-containing material. The protection layers are resistant during etching during the methods described herein.

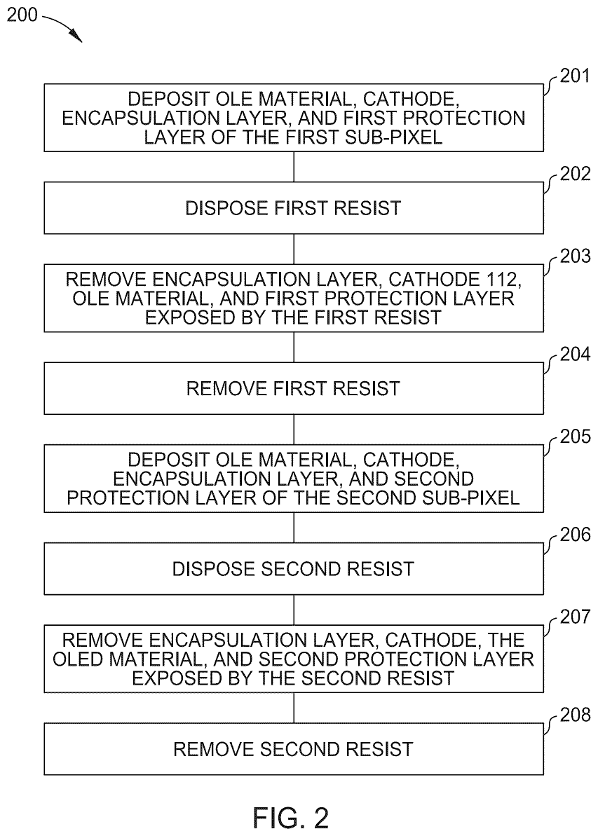

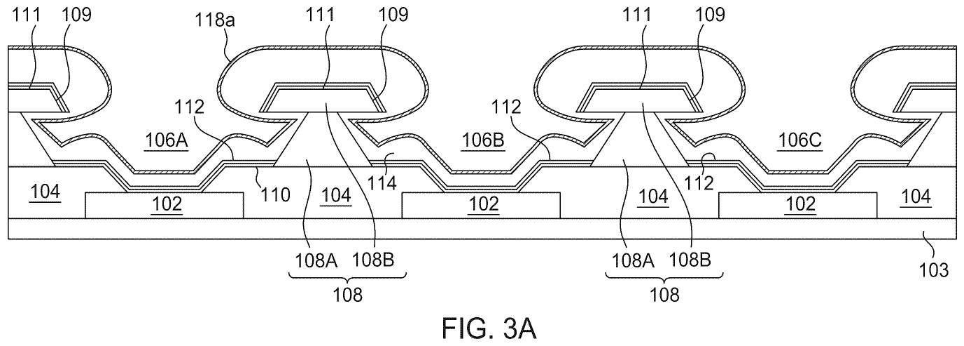

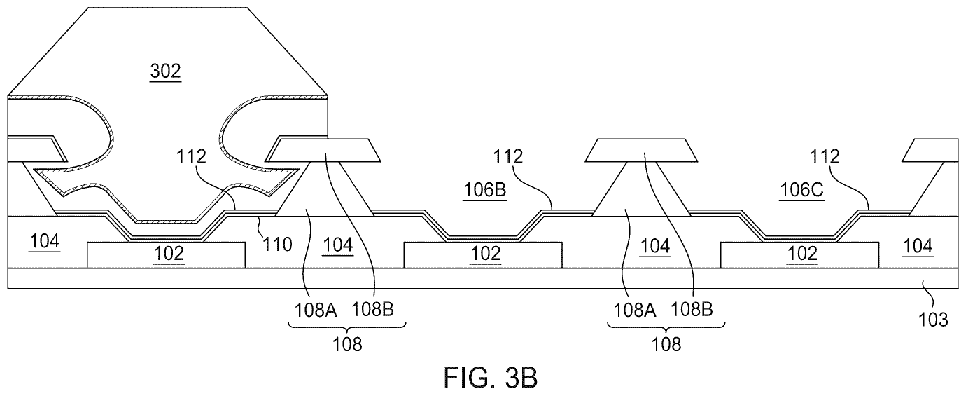

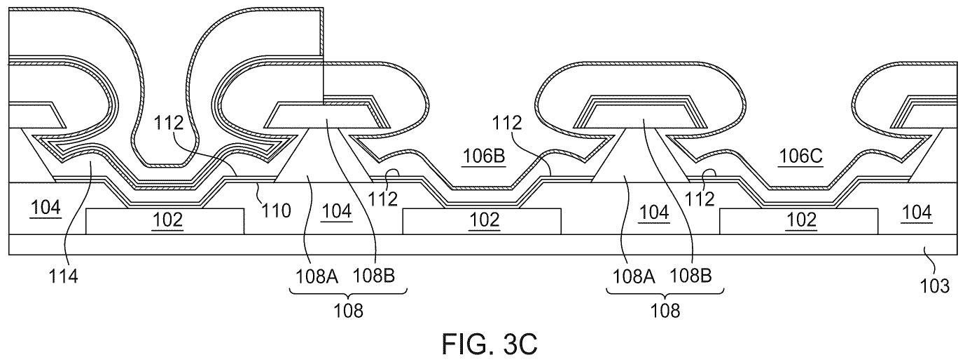

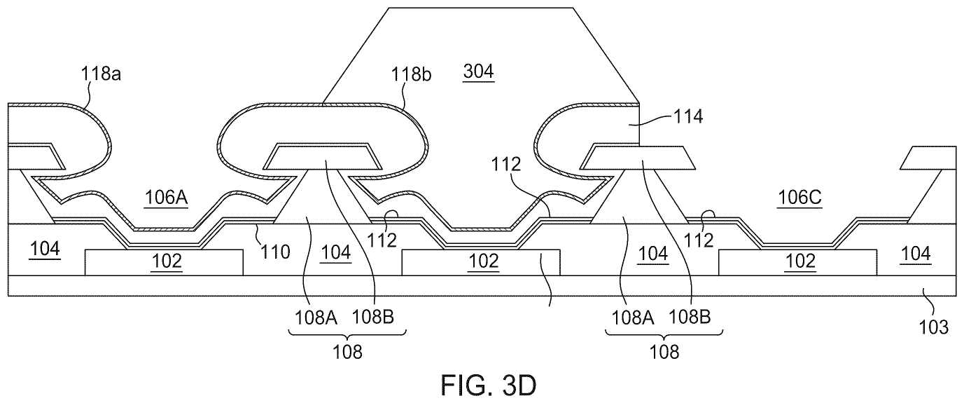

FIG. 2 is a flow diagram of a method 200 for forming a sub-pixel circuit 100 having the first protection configuration 101A. FIGS. 3A-3D are schematic, cross-sectional views of a substrate 103 during the method 200 for forming the sub-pixel circuit 100.

At operation 201, as shown in FIG. 3A, the OLE material 110, the cathode 112, the encapsulation layer 114, and the first protection layer 118a are deposited. Prior to operation 301, the overhang structures 108 are fabricated over the substrate 103. The OLE material 110, the cathode 112, the encapsulation layer 114, and the first protection layer 118a are deposited over the substrate 103 with the overhang structures 108. At operation 202, a first resist 302 is disposed in a well of the first sub-pixel 106A. The first resist 302 is disposed over the entirety of the substrate and subsequently patterned to be disposed in a well of the first sub-pixel 106A. At operation 203, as shown in FIG. 3B, the encapsulation layer 114, the cathode 112, the OLE material 110, and the first protection layer 118a exposed by the first resist 302 are removed. The first protection layer 118a exposed by the first resist 302 is removed by a first etch process. The encapsulation layer 114 may be removed by a second etch process. The first etch process and the second etch process may include different chemistries. The first etch process is a wet etch process or dry etch process. The second etch process is a dry etch process. At operation 204, first resist 302 is removed.

At operation 205, as shown in FIG. 3C, the OLE material 110, the cathode 112, the encapsulation layer 114, and the second protection layer 118b of the second sub-pixel 106B are deposited. The OLE material 110 of the second sub-pixel 106B is disposed on or over the first protection layer 118a of the first sub-pixel 106A. The composition of the first protection layer 118a may allow the first protection layer 118a to resist plasma etching during removal of the exposed encapsulation layer 114 over the first sub-pixel 106A. At operation 206, a second resist 304 is disposed in a well of the second sub-pixel 106B. The second resist 304 is disposed over the entirety of the substrate and subsequently patterned to be disposed in a well of the second sub-pixel 106B. At operation 207, as shown in FIG. 3D, the encapsulation layer 114, the cathode 112, the OLE material 110, and the second protection layer 118b exposed by the second resist 304 are removed. The second protection layer 118b is removed by the first etch process. The encapsulation layer 114 is removed by the second etch process. The first etch process and the second etch process may include different chemistries. The first etch process is a wet etch process or dry etch process. The second etch process is a dry etch process. The composition of the first protection layer 118a may allow the first protection layer 118a to resist plasma etching during the removal of the exposed encapsulation layer 114. Thus, the encapsulation layer 114, the cathode 112, the OLE material 110 of the first sub-pixel 106A are protected. At operation 208, the second resist 304 is removed.

As shown in FIG. 1A, operations 205-208 are repeated for the third sub-pixel 106C, such that the third sub-pixel 106C has the OLE material 110, the cathode 112, and the encapsulation layer 114. The third protection layer 118c is an optional layer. The composition of the second protection layer 118b and the first protection layer 118a provide for etch resistance during the exposed encapsulation layer 114. Thus, the encapsulation layer 114, the cathode 112, the OLE material 110 of the first sub-pixel 106A and the second sub-pixel are protected. After operations 205-208, the sub-pixel circuit 100 having the first protection configuration 101A is formed. The first, second, and third protection layers 118a, 118b, 118c are optionally removed.

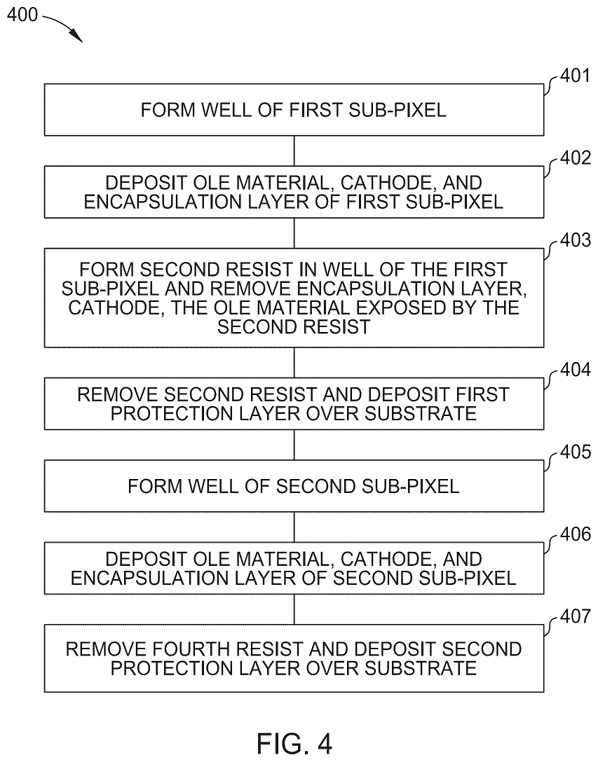

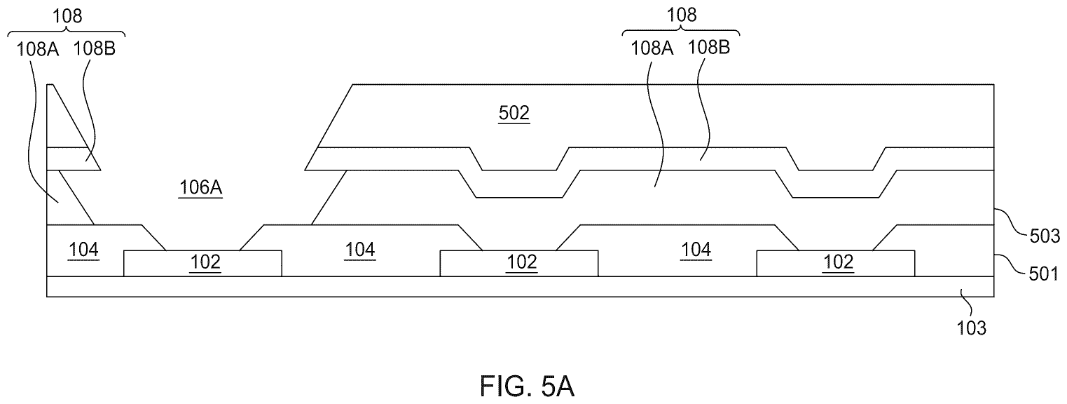

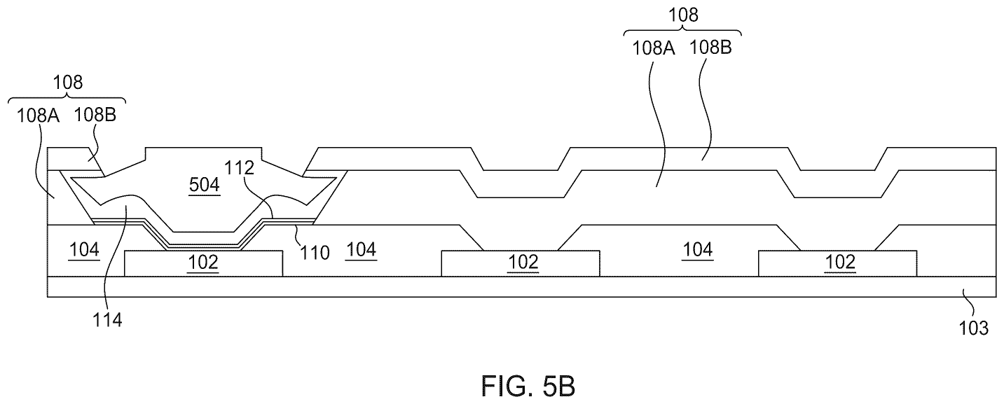

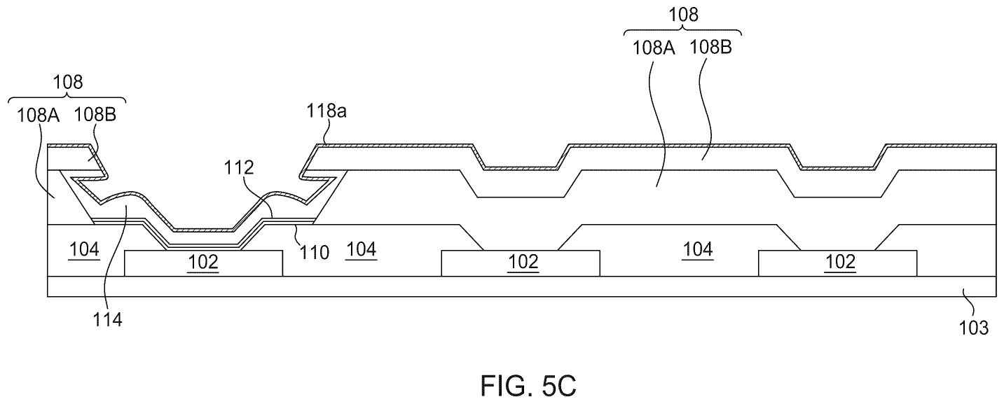

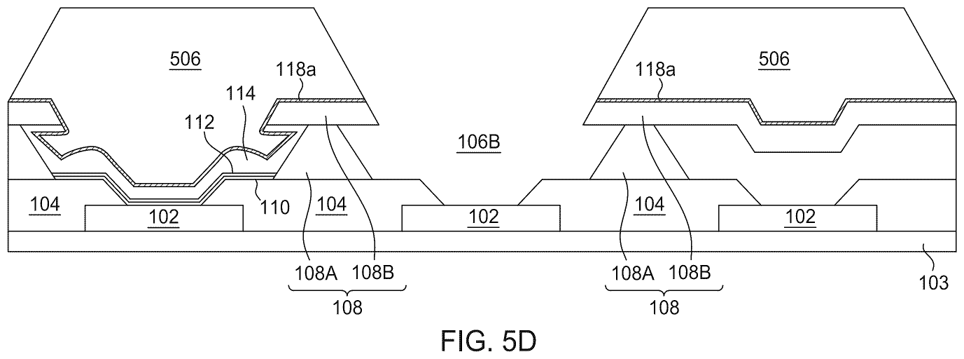

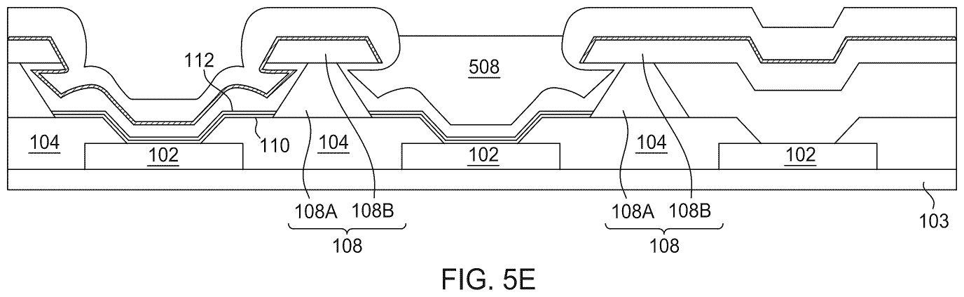

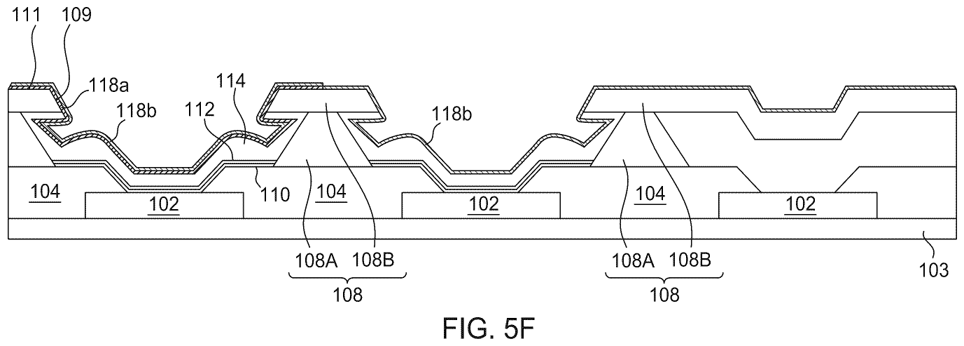

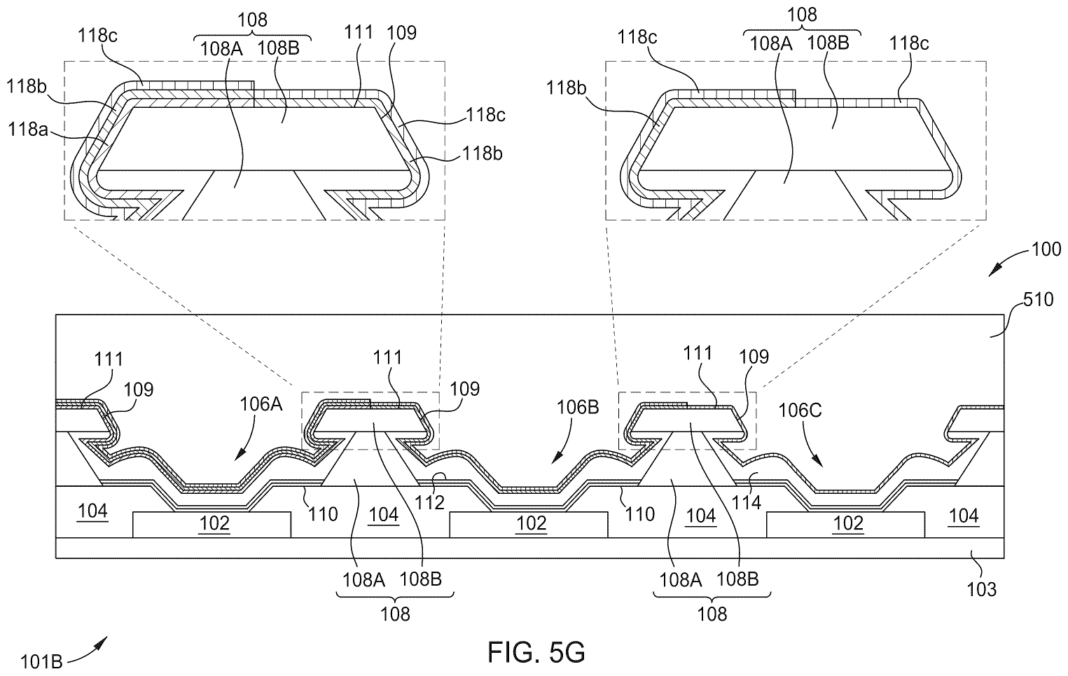

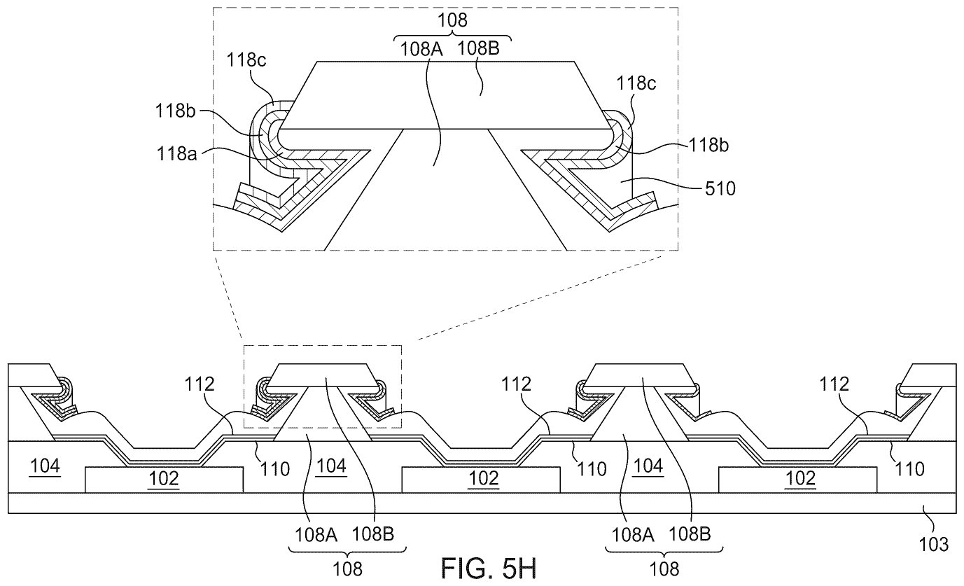

FIG. 4 is a flow diagram of a method 400 for forming a sub-pixel circuit 100. FIGS. 5A-5H are schematic, cross-sectional views of a substrate 103 during the method 400 for forming the sub-pixel circuit 100.

At operation 401, as shown in FIG. 5A, a well of a first sub-pixel 106A is formed. The well of a first sub-pixel 106A is formed by depositing a first structure layer 501 and a second structure layer 503 over the substrate 103. The first structure layer 501 corresponds to the first structure 108A. The second structure layer 503 corresponds to the second structure 108B. A first resist 502 is disposed and patterned such that an area of the first sub-pixel 106A to be formed is exposed. The exposed second structure layer 503 and the first structure layer 501 are etched to form the well of the first sub-pixel 106A. The first resist 502 is then removed. At operation 402, the OLE material 110, the cathode 112, and the encapsulation layer 114 are deposited. At operation 403, a second resist 504 is formed in the well of the first sub-pixel 106A and, as shown in FIG. 5B, the encapsulation layer 114, the cathode 112, the OLE material 110 exposed by the second resist 504 are removed. The second resist 504 is disposed over the entirety of the substrate and subsequently patterned to be disposed in a well of the first sub-pixel 106A. At operation 404, as shown in FIG. 5C, the second resist 504 is removed and the first protection layer 118a is deposited over the substrate 103.

At operation 405, as shown in FIG. 5D, a well of a second sub-pixel 106B is formed. A third resist 506 is disposed and patterned to expose an area of the second sub-pixel 106B to be formed. The first protection layer 118a exposed by the resist in the area of the second sub-pixel 106B is removed. The first protection layer 118a is removed by the first etch process. At operation 406, as shown in FIG. 5E, the OLE material 110, the cathode 112, and the encapsulation layer 114 of the second sub-pixel 106B are deposited. A fourth resist 508 is formed in the well of the second sub-pixel 106B. The fourth resist 508 is disposed over the entirety of the substrate and subsequently patterned to be disposed in a well of the second sub-pixel 106B. The encapsulation layer 114, the cathode 112, the OLE material 110 exposed by the third resist 506 are removed. The composition of the first protection layer 118a may allow the first protection layer 118a to resist plasma etching during the removal of the exposed material. Thus, the encapsulation layer 114, the cathode 112, the OLE material 110 of the first sub-pixel 106A are protected.

At operation 407, as shown in FIG. 5F, the resist fourth resist 508 is removed and the second protection layer 118b is deposited over the substrate 103. As shown in FIG. 1B, operations 404-406 are repeated for the third sub-pixel 106C, such that the third sub-pixel 106C has the OLE material 110, the cathode 112, and the encapsulation layer 114. The third protection layer 118c is an optional layer. The composition of the second protection layer 118b and the first protection layer 118a provide for etch resistance during the removal of the exposed material. Thus, the encapsulation layer 114, the cathode 112, the OLE material 110 of the first sub-pixel 106A and the second sub-pixel are protected.

After the operations of the method 400, the sub-pixel circuit 100 having the second protection configuration 101B is formed. In some embodiments, the first, second, and third protection layers 118a, 118b, 118c are removed. In other embodiments, as shown in FIG. 5G, a global resist 510 is disposed over the first, second, and third sub-pixels 106A, 106B, 106C. As shown in FIG. 5h, the global resist 510 is ashed. The global resist 510 is ashed by ashing process. The ashing process uses an oxygen plasma. A portion, residual, of the global resist 510 remains such that the first, second, and third protection layers 118a, 118b, 118c over the upper surface of the second structure 108B and a portion of the first, second, and third protection layers 118a, 118b, 118c in the wells are exposed. The exposed the first, second, and third protection layers 118a, 118b, 118c are removed. The exposed first, second, and third protection layers 118a, 118b, 118c may be removed by an etching process. The exposed first, second, and third protection layers 118a, 118b, 118c may be removed by an etching process using oxalic acid. The remaining global resist 510 is then removed.

Removing the exposed first, second, and third protection layers 118a, 118b, 118c provides for the third protection configuration 101C. As shown in FIG. 1C of the third protection configuration 101C, the first protection contacts the bottom surface of the second structure 108B of the overhang structures 108 and extends under at least a portion of the overhang structures 108 along a sidewall of the first structure 108A. The first sub-pixel 106A includes the second protection layer 118b disposed over the first protection layer 118a. The second protection layer 118b is disposed adjacent to the upper sidewall 109 of the second structure 108B. The third protection layer 118c is disposed over the second protection layer 118b in the first sub-pixel 106A. The second protection layer contacts the bottom surface of the second structure 108B of the overhang structures 108 and extends under at least a portion of the overhang structures 108 along a sidewall of the first structure 108A. The second sub-pixel 106B includes the third protection layer 118c disposed over the second protection layer 118b. The third protection layer 118c is disposed adjacent to the upper sidewall 109 of the second structure 108B. The third protection layer 118c of the third sub-pixel 106C contacts the bottom surface of the second structure 108B of the overhang structures 108, and extends under at least a portion of the overhang structures 108 along a sidewall of the first structure 108A. After the exposed first, second, and third protection layers 118a, 118b, 118c are removed, the global resist 510 is stripped.

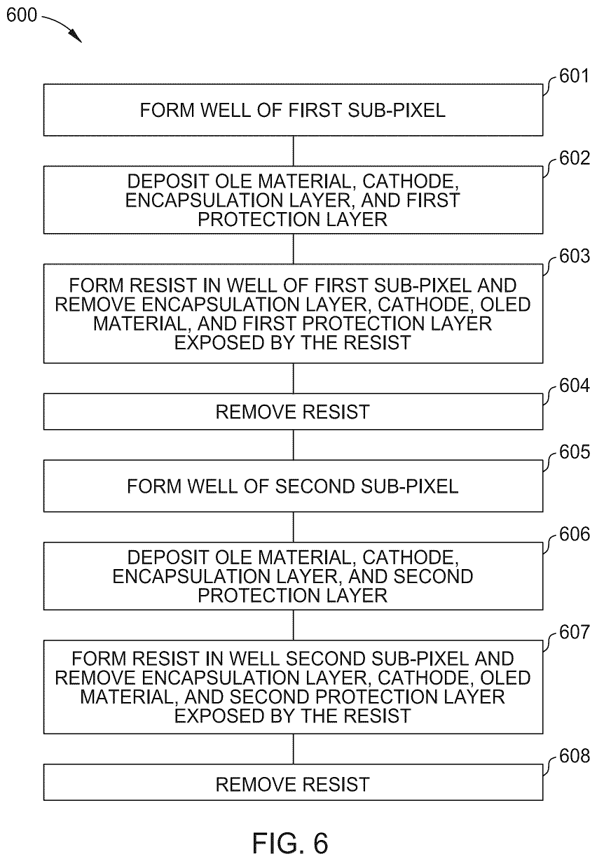

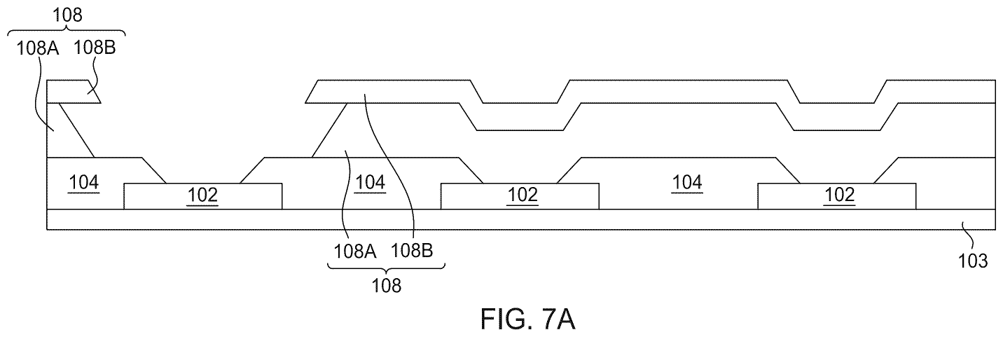

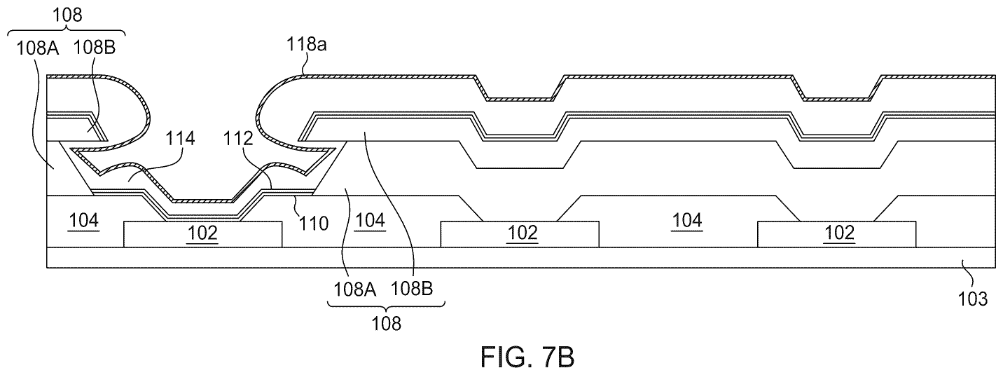

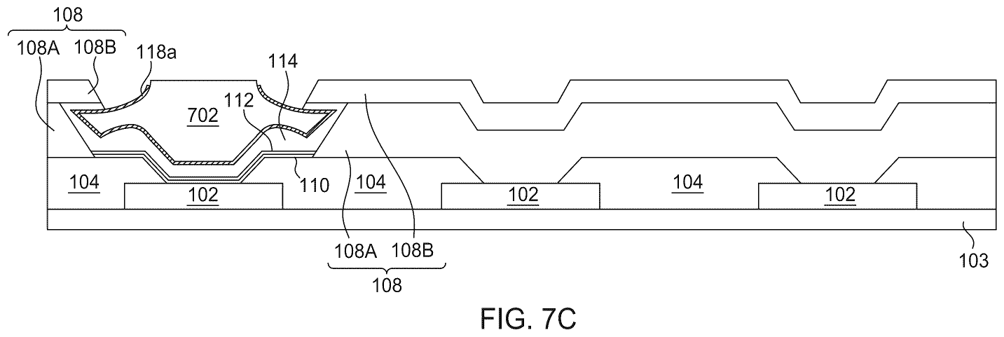

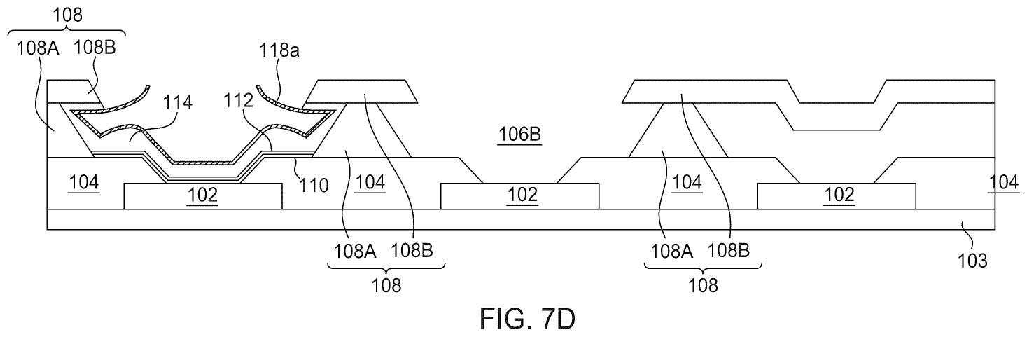

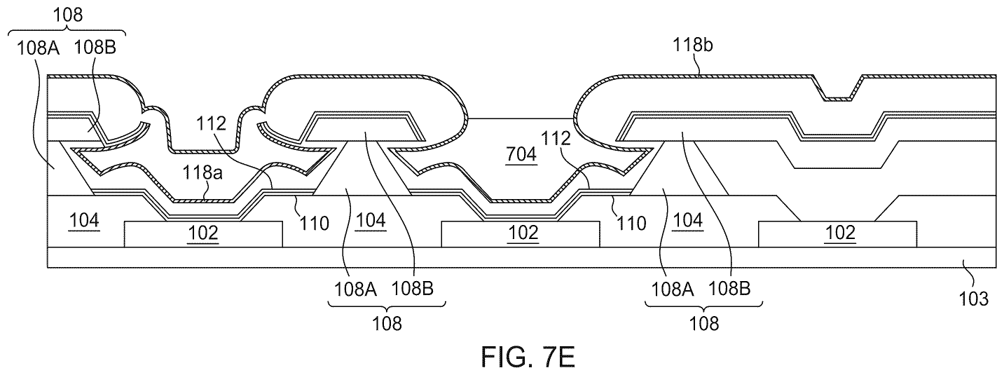

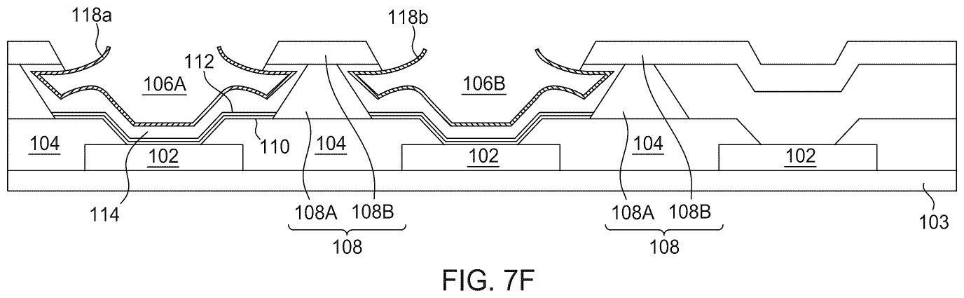

FIG. 6 is a flow diagram of a method 600 for forming a sub-pixel circuit 100 having the fourth protection configuration 101D. FIGS. 7A-7F are schematic, cross-sectional views of a substrate 103 during the method 600 for forming the sub-pixel circuit 100.

At operation 601, as shown in FIG. 7A, a well of a first sub-pixel 106A is formed. The well of a first sub-pixel 106A is formed by depositing a first structure layer 501 and a second structure layer 503 over the substrate 103. The first structure layer 501 corresponds to the first structure 108A. The second structure layer 503 corresponds to the second structure 108B. A resist is disposed and patterned such that an area of the first sub-pixel 106A to be formed is exposed. The exposed second structure layer 503 and the first structure layer 501 are etched to form the well of the first sub-pixel 106A. At operation 602, as shown in FIG. 7B, the OLE material 110, the cathode 112, the encapsulation layer 114, and the first protection layer 118a are deposited. At operation 603, a resist 702 is formed in the well of the first sub-pixel 106A and, as shown in FIG. 7C, the encapsulation layer 114, the cathode 112, the OLE material 110, and the first protection layer 118a exposed by the resist 702 are removed. The resist 702 is disposed over the entirety of the substrate and subsequently patterned to be disposed in a well of the first sub-pixel 106A. The first protection layer 118a is removed by a first etch process. The encapsulation layer 114 may be removed by a second etch process. The first etch process and the second etch process may include different chemistries. The first etch process is a wet etch process or dry etch process. The second etch process is a dry etch process. At operation 604, the resist 702 is removed.

At operation 605, as shown in FIG. 7D, a well of a second sub-pixel 106B is formed. A resist is disposed and patterned to expose an area of the second sub-pixel 106B to be formed. The second structure layer 503 and the first structure layer 501 exposed by the resist are etched. At operation 606, the cathode 112, the encapsulation layer 114, and the second protection layer 118b of the second sub-pixel 106B are deposited. At operation 607, a resist 704 is then formed in the well of the second sub-pixel 106B, and the encapsulation layer 114, the cathode 112, the OLE material 110, and the second protection layer 118b exposed by a resist 704 are removed. As shown in FIG. 7F, the resist 704 is then removed at operation 608. The resist 704 is disposed over the entirety of the substrate and subsequently patterned to be disposed in a well of the second sub-pixel 106B. The composition of the first protection layer 118a may allow the first protection layer 118a to resist plasma etching during the removal of the exposed encapsulation layer 114. Thus, the encapsulation layer 114, the cathode 112, the OLE material 110 of the first sub-pixel 106A are protected.

As shown in FIG. 1D, operations 605-608 are repeated for the third sub-pixel 106C, such that the third sub-pixel 106C has the OLE material 110, the cathode 112, and the encapsulation layer 114. The third protection layer 118c is an optional layer. The composition of the second protection layer 118b and the first protection layer 118a provide for etch resistance during the removal of the exposed encapsulation layer 114. Thus, the encapsulation layer 114, the cathode 112, the OLE material 110 of the first sub-pixel 106A and the second sub-pixel 106B are protected.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a substrate;
a plurality of overhang structures, each overhang structure defined a second structure disposed over a first structure, the second structure extending laterally past the first structure, adjacent overhang structures of the plurality overhang structures define a plurality of sub-pixels including a first sub-pixel and a second sub-pixel;
the first sub-pixel comprising:
a first anode;
a first organic light-emitting (OLE) material;
a first cathode disposed over the first OLE material;
a first encapsulation layer;
a first protection layer disposed on the first encapsulation layer extending under at least a portion of the overhang structures and along a sidewall of the first structure; and
the second sub-pixel comprising:
a second anode;
a second OLE material;
a second cathode disposed over the second OLE material;
a second encapsulation layer; and
a second protection layer disposed on the second encapsulation layer extending under at least the portion of the overhang structures and along the sidewall of the first structure.

2. The device of claim 1, wherein:
the first protection layer is disposed over the first encapsulation layer contacting a bottom surface of the second structure and over an upper sidewall of the second structure; and
the second protection layer is disposed over the second encapsulation layer contacting the bottom surface of the second structure and over the upper sidewall of the second structure.

3. The device of claim 1, wherein:
the first protection layer and the first encapsulation layer have a gap therebetween; and
the second protection layer and the second encapsulation layer have the gap therebetween.

4. The device of claim 1, wherein the first protection layer and the second protection layer include a metal-containing material, a transparent conductive oxide (TCO) containing material, or a dielectric-containing material.

5. The device of claim 1, further comprising a third sub-pixel, the third sub-pixel having:
a third anode;
a third organic light-emitting (OLE) material;
a third cathode disposed over the third OLE material;
a third encapsulation layer; and
a third protection layer disposed on the third encapsulation layer extending under at least the portion of the overhang structures and along the sidewall of the first structure.

6. A device, comprising:
a substrate;
a plurality of overhang structures, each overhang structure defined a second structure disposed over a first structure, the second structure extending laterally past the first structure, adjacent overhang structures of the plurality overhang structures define a plurality of sub-pixels including a first sub-pixel and a second sub-pixel;
the first sub-pixel comprising:
a first anode;
a first organic light-emitting (OLE) material;
a first cathode disposed over the first OLE material;
a first encapsulation layer;
a first protection layer disposed on the first encapsulation layer extending under at least a portion of the overhang structures and along a sidewall of the first structure; and
a second protection layer disposed on the first protection layer, and the second sub-pixel comprising:
a second anode;
a second OLE material;
a second cathode disposed over the second OLE material;
a second encapsulation layer; and
the second protection layer disposed on the second encapsulation layer extending under at least the portion of the overhang structures and along the sidewall of the first structure.

7. The device of claim 6, wherein:
the first protection layer of the first sub-pixel is disposed over the first encapsulation layer contacting a bottom surface of the second structure, the first protection layer is disposed over an upper sidewall and an upper surface of the second structure; and
the second protection layer of the second sub-pixel is disposed over the second encapsulation layer contacting the bottom surface of the second structure, the first protection layer is disposed over the upper sidewall and the upper surface of the second structure.

8. The device of claim 6, wherein:
the first protection layer of the first sub-pixel extends past the first encapsulation layer to contact a bottom surface of the second structure; and
the second protection layer of the second sub-pixel extends past the second encapsulation layer to contact the bottom surface of the second structure.

9. The device of claim 6, wherein the first protection layer and the second protection layer include a metal-containing material, a transparent conductive oxide (TCO) containing material, or a dielectric-containing material.

10. The device of claim 6, further comprising a third sub-pixel, the third sub-pixel having:
a third anode;
a third organic light-emitting (OLE) material;
a third cathode disposed over the third OLE material;
a third encapsulation layer; and
a third protection layer disposed on the third encapsulation layer extending under at least the portion of the overhang structures and along the sidewall of the first structure.

11. A method, comprising:
disposing a first organic light-emitting (OLE) material, a first cathode, a first encapsulation layer, and a first protection layer over a substrate, the substrate having:
a plurality of overhang structures, each overhang structure is defined by a second structure disposed over a first structure, the second structure extending laterally past the first structure, adjacent overhang structures of the plurality overhang structures define a plurality of sub-pixels including at least a first sub-pixel and a second sub-pixel;
forming a resist in a well of the first sub-pixel;
removing the first protection layer, the first cathode, the first OLE material, and the first encapsulation layer exposed by the resist;
removing the resist in the well of the first sub-pixel;
disposing a second OLE material, a second cathode, a second encapsulation layer, and a second protection layer over the substrate;
forming a resist in the well of the second sub-pixel; and
removing the second protection layer, the second cathode, and the second OLE material, and the second encapsulation layer exposed by the resist.

12. The method of claim 11, wherein:
the first protection layer is disposed over the first encapsulation layer contacting a bottom surface of the second structure and over an upper sidewall of the second structure; and
the second protection layer is disposed over the second encapsulation layer contacting the bottom surface of the second structure and over the upper sidewall of the second structure.

13. The method of claim 11, further comprising forming a third sub-pixel, the third sub-pixel having:
a third anode;
a third organic light-emitting (OLE) material;
a third cathode disposed over the first OLE material;
a third encapsulation layer; and
a third protection layer.

14. The method of claim 11, wherein the first protection layer and the second protection layer include a metal-containing material, a transparent conductive oxide (TCO) containing material, or a dielectric-containing material.

15. A method, comprising:
providing a substrate having a first well of a first sub-pixel defined by adjacent overhang structures disposed over the substrate;
disposing a first organic light-emitting (OLE) material, a first cathode, and a first encapsulation layer;
forming a first resist in a well of the first sub-pixel;
removing the first OLE material, the first cathode, and the first encapsulation layer exposed by the first resist;
removing the first resist;
disposing a first protection layer over the substrate;
forming a second resist over the first sub-pixel to expose an area of a second sub-pixel;
etching a second layer and a first layer to form a well of a second sub-pixel;
disposing a second OLE material, a second cathode, and a second encapsulation layer over the substrate;
forming a third resist in the well of the second sub-pixel;
removing the second OLE material, the second cathode, and the second encapsulation layer exposed by the third resist; and
depositing a second protection layer over the substrate.

16. The method of claim 15, further comprising:
forming a fourth resist over the first sub-pixel and second sub-pixel to expose an area of a third sub-pixel;
etching the second layer and the first layer to form a well of a third sub-pixel;
disposing a third OLE material, a third cathode, and a third encapsulation layer over the substrate; and
removing the third OLE material, the third cathode, and the third encapsulation layer exposed by the fourth resist.

17. The method of claim 16, further comprising depositing a third protection layer over the substrate.

18. The method of claim 15, further comprising:
disposing a global resist over wells of the first sub-pixel and the second sub-pixel;
conducting an ashing process; and
conducting an etching process to remove second protection layer and first protection layer exposed by residual global resist material.

19. A method, comprising:
providing a substrate having a first well of a first sub-pixel defined by adjacent overhang structures disposed over the substrate;
disposing a first organic light-emitting (OLE) material, a first cathode, a first encapsulation layer, and a first protective layer;
forming a first resist in a well of the first sub-pixel;
removing the first OLE material, the first cathode, the first encapsulation layer, and the first protective layer exposed by the first resist;
removing the first resist;
forming a second resist over the first sub-pixel to expose an area of a second sub-pixel;
etching a second layer and a first layer to form a well of a second sub-pixel;
disposing a second OLE material, a second cathode, a second encapsulation layer, and a second protective layer over the substrate;
forming a third resist in the well of the second sub-pixel;
removing the second OLE material, the second cathode, the second encapsulation layer, and the second protection layer exposed by the third resist; and
removing the third resist.

20. The method of claim 19, wherein:
the first protection layer and the first encapsulation layer have a gap therebetween; and
the second protection layer and the second encapsulation layer have the gap therebetween.
